(19) United States
(12) Patent Application Publication
(10) Pub. No.: US 2025/0262922 A1
(43) Pub. Date: Aug. 21, 2025

(54) INTEGRATED ELECTRIC DRIVE SYSTEM AND ELECTRIC VEHICLE

(71) Applicant: BYD COMPANY LIMITED, SHENZHEN (CN)

(72) Inventors: Heping LING, Shenzhen (CN); Zhen ZHAI, Shenzhen (CN); Lei HU, Shenzhen (CN); Yuchao XIONG, Shenzhen (CN)

(21) Appl. No.: 19/199,803

(22) Filed: May 6, 2025

Related U.S. Application Data
(63) Continuation of application No. 18/128,666, filed on Mar. 30, 2023.
Application No. 18/128,666 is a continuation of application No. PCT/CN2021/121798, filed on Sep. 29, 2021.

(30) Foreign Application Priority Data
Sep. 30, 2020 (CN) 202011063762.8

(51) Int. Cl. B60K 1/00; B60K 17/04; B60L 15/20; B60L 50/60; H02J 7/00; H02K 3/50; H02K 5/20; H02K 7/116; H02K 9/19; H02K 11/00; H02K 11/33

(52) U.S. Cl. CPC B60K 1/00; B60K 17/04; B60L 15/20; B60L 50/60; H02J 7/0042; H02K 3/50; H02K 5/203; H02K 7/116; H02K 9/19; H02K 11/0094; H02K 11/33; H02K 2203/09; H02K 2211/03

(57) ABSTRACT

An integrated electric drive system and an electric vehicle are provided. The integrated electric drive system includes a motor, a speed reducer, a controller, and a single-piece enclosure. A first enclosure space is formed on the single-piece enclosure, and a second enclosure space and a third enclosure space configured for the speed reducer to be mounted are arranged on the single-piece enclosure. The motor controller is connected with the motor. An output shaft of the motor is connected with the speed reducer. An absolute value of a difference between a preset mounting width value and a width value of the first enclosure space is less than or equal to a first difference threshold. An absolute value of a difference between a length value of the first enclosure space and a length value of the third enclosure space is less than or equal to a second difference threshold.

### CROSS-REFERENCE TO RELATED APPLICATIONS

This application is a continuation application of U.S. patent application Ser. No. 18/128,666, filed on Mar. 30, 2023, which is a Continuation Application of International Patent Application No. PCT/CN2021/121798, filed on Sep. 29, 2021, which is based on and claims priority to and benefits of Chinese Patent Application No. 202011063762.8, filed on Sep. 30, 2020. The entire content of all of the above-referenced applications is incorporated herein by reference.

### FIELD

The present disclosure relates to the technical field of electric vehicles, and more specifically, to an integrated electric drive system and an electric vehicle.

### BACKGROUND

An electric drive system is a core component of an electric vehicle. With the continuous development of new energy vehicles, there are increasingly high requirements for the arrangement of the vehicle driving system. The electric drive system is composed of components such as a driving motor, a motor controller, a transmission, an air compressor, a water pump, a vehicle controller, an on-board charger, and a DC converter. In the related art, an integrated control enclosure of the electric drive system is generally mounted to a top of a stator enclosure of the driving motor, the transmission is mounted to an output shaft end of the driving motor, and the air compressor is hung on the transmission through a support. However, such an integrated electric drive system has disadvantages such as a large overall weight, a low integration level, a large enclosure space, and high costs of molds and materials, and the like.

### SUMMARY

The present disclosure provides an integrated electric drive system and an electric vehicle, so as to solve the technical problems such as a low integration level and a large enclosure space of the electric drive system in the related art.

In view of the above problems, an integrated electric drive system provided in an example of the present disclosure includes a motor, a speed reducer, a controller, and a single-piece enclosure. A first enclosure space having a first opening and configured for the controller to be mounted is recessed on the single-piece enclosure. A second enclosure space configured for the motor to be mounted and a third enclosure space configured for the speed reducer to be mounted are arranged in a direction of the single-piece enclosure facing away from the first opening. The controller is connected with the motor. An output shaft of the motor is connected with the speed reducer.

An absolute value of a difference between a preset mounting width value and a width value of the first enclosure space is less than or equal to a first difference threshold in a direction parallel to the output shaft of the motor. The preset mounting width value is a sum of a width value of the second enclosure space and a width value of the third enclosure space.

An absolute value of a difference between a length value of the first enclosure space and a length value of the third enclosure space is less than or equal to a second difference threshold in a direction perpendicular to the output shaft of the motor and parallel to a horizontal plane.

In some examples of the present disclosure, an absolute value of a difference between a half of the length value of the first enclosure space and the length value of the second enclosure space is less than or equal to a third difference threshold in the direction perpendicular to the output shaft of the motor and parallel to the horizontal plane.

In some examples of the present disclosure, the first difference threshold is zero.

In some examples of the present disclosure, the second difference threshold is zero.

In some examples of the present disclosure, the third difference threshold is zero.

In some examples of the present disclosure, the integrated electric drive system further includes an air conditioning compressor and a support mounted on an end surface of the speed reducer away from the second enclosure space. The air conditioning compressor is mounted to the support and connected with the controller.

In some examples of the present disclosure, the integrated electric drive system further includes a water pump mounted to the support and connected with the controller.

In some examples of the present disclosure, the support includes a vertical plate and a transverse plate connected with an upper end of the vertical plate. The vertical plate is mounted to an end surface of the speed reducer away from the motor, the water pump is mounted above the transverse plate, and the air conditioning compressor is mounted to a side of the vertical plate away from the speed reducer and is located below the transverse plate.

In some examples of the present disclosure, the controller includes a capacitor module, an IGBT module, a three-phase copper bar, a DC bus, an on-board charger, and a DC converter. The on-board charger and the DC converter are both connected with a vehicle power battery. The capacitor module, the IGBT module, the three-phase copper bar, the on-board charger, and the DC converter are all mounted in the first enclosure space. The capacitor module is connected with the vehicle power battery through the DC bus mounted to the single-piece enclosure. The three-phase copper bar is connected with a three-phase terminal of the motor.

The vehicle power battery drives the motor to rotate through the DC bus, the capacitor module, the IGBT module, and the three-phase copper bar connected in sequence.

In some examples of the present disclosure, the on-board charger and the DC converter include a heat dissipation module, an electric control element driving module, and a heating element driving module. The heating element driving module is mounted to the heat dissipation module, and the electric control element driving module is mounted to an end of the heating element driving module away from the heat dissipation module.

In some examples of the present disclosure, the first enclosure space includes a first internal space and a second internal space both arranged in a rectangular shape and adjacent to each other.

The capacitor module, the IGBT module, and the three-phase copper bar are all mounted in the first internal space. The on-board charger and the DC converter are mounted in the second internal space, and the DC bus is located on a side of the first internal space facing away from the second internal space.

In some examples of the present disclosure, the single-piece enclosure includes a first cooling water channel, a second cooling water channel, a water channel inlet, and a water channel outlet. The first cooling water channel is arranged at a position in the single-piece enclosure opposite to the IGBT module, and the second cooling water channel is arranged at a position in the single-piece enclosure opposite to the on-board charger and the DC converter.

One end of the water channel inlet is connected with a preset water inlet device, the other end of the water channel inlet is connected with the first cooling water channel and the second cooling water channel, and the water channel outlet is connected with ends of the first cooling water channel and the second cooling water channel away from the water channel inlet.

In some examples of the present disclosure, the motor includes an outer enclosure connected with the speed reducer and an inner enclosure inserted in the outer enclosure. A cooling space is formed between an inner wall of the outer enclosure and an outer wall of the inner enclosure. A water inlet and a water outlet both in communication with the cooling space are arranged on the outer enclosure. An end of the water channel outlet away from the first cooling water channel is in communication with the water inlet.

In some examples of the present disclosure, multiple ribbed flow guide plates are arranged on the outer wall of the inner enclosure in a circumferential direction of the output shaft of the motor.

In some examples of the present disclosure, the speed reducer includes a main shaft, an intermediate shaft, an output shaft, a driving gear, an output gear, an intermediate driving gear, and an intermediate driven gear. The main shaft is connected with the output shaft of the motor. The driving gear is mounted to the main shaft, the intermediate driving gear and the intermediate driven gear are both mounted to the intermediate shaft, and the output gear is mounted to the output shaft of the speed reducer. The intermediate driving gear is meshed with the driving gear, and the intermediate driven gear is meshed with the output gear.

An axis of the intermediate shaft is higher than axes of the main shaft and the output shaft of the speed reducer. An included angle between a line connecting a center point of the main shaft to a center point of the output shaft of the speed reducer and the horizontal plane is less than or equal to a preset angle on a plane perpendicular to the axis of the main shaft.

In some examples of the present disclosure, a battery mounting space configured for a battery to be mounted is arranged on an end surface of the single-piece enclosure facing away from the first opening.

In some examples of the present disclosure, the integrated electric drive system further includes an enclosure cover adaptively connected with the first opening.

In the present disclosure, the integrated electric drive system integrates the controller, the motor, and the speed reducer. The controller is mounted in the first enclosure space within the single-piece enclosure, and the motor and the speed reducer are respectively mounted in the second enclosure space and the third enclosure space below the single-piece enclosure. In addition, an absolute value of a difference between a sum of the width value of the second enclosure space and the width value of the third enclosure space and the width value of the first enclosure space is less than or equal to the first difference threshold. The absolute value of the difference between the length value of the first enclosure space and the length value of the third enclosure space is less than or equal to the second difference threshold in the direction perpendicular to the output shaft of the motor and parallel to a horizontal plane. Through above arrangement, the mounting spaces of the integrated electric drive system in all directions are more balanced, and no large hanging space is left in all directions, which improves the modality of the single-piece enclosure and noise, vibration, and harshness (NVH) of the vehicle. In addition, the integrated electric drive system has a high integration level, which reduces the mounting space of the integrated electric drive system on the vehicle, thereby providing a space for a larger motor. Moreover, a complex wiring harness connection between the components is omitted in the integrated electric drive system with the high integration level.

An example of the present disclosure further provides an electric vehicle, including the above integrated electric drive system.

Additional aspects and advantages of the present disclosure are to be partially given in the following description, and partially become apparent in the following description or understood through the practice of the present disclosure.

### BRIEF DESCRIPTION OF THE DRAWINGS

FIG. 1 is a schematic diagram of an exploded structure of an integrated electric drive system according to an example of the present disclosure.

FIG. 2 is a schematic diagram of an assembly structure of an integrated electric drive system according to an example of the present disclosure.

FIG. 3 is a schematic diagram showing arrangement of a first enclosure space, a second enclosure space, and a third enclosure space of an integrated electric drive system according to an example of the present disclosure.

FIG. 4 is a schematic structural diagram of an integrated electric drive system according to an example of the present disclosure.

FIG. 5 is a schematic structural diagram of a controller of an integrated electric drive system according to an example of the present disclosure.

FIG. 6 is a schematic structural diagram of an on-board charger and a DC converter of an integrated electric drive system according to an example of the present disclosure.

FIG. 7 is a schematic diagram of a first cooling water channel and a second cooling water channel of an integrated electric drive system according to an example of the present disclosure.

FIG. 8 is a schematic structural diagram of a speed reducer of an integrated electric drive system according to an example of the present disclosure.

### DETAILED DESCRIPTION

In order to make the technical problems, technical solutions, and beneficial effects to be solved in the present disclosure clearer, the present disclosure is further described in detail below with reference to the accompanying drawings and examples. It should be understood that the specific examples described herein are merely used to explain the present disclosure but are not intended to limit the present disclosure.

It should be understood that orientation or position relationships indicated by the terms such as “up”, “down”, “left”, “right”, “front”, “back”, and “middle” are based on orientation or position relationships shown in the accompanying drawings, and are used only for ease of description of the present disclosure and brevity of the description, rather than indicating or implying that the mentioned apparatus or element need to have a particular orientation or be constructed and operated in a particular orientation. Therefore, such terms should not be construed as a limitation on the present disclosure.

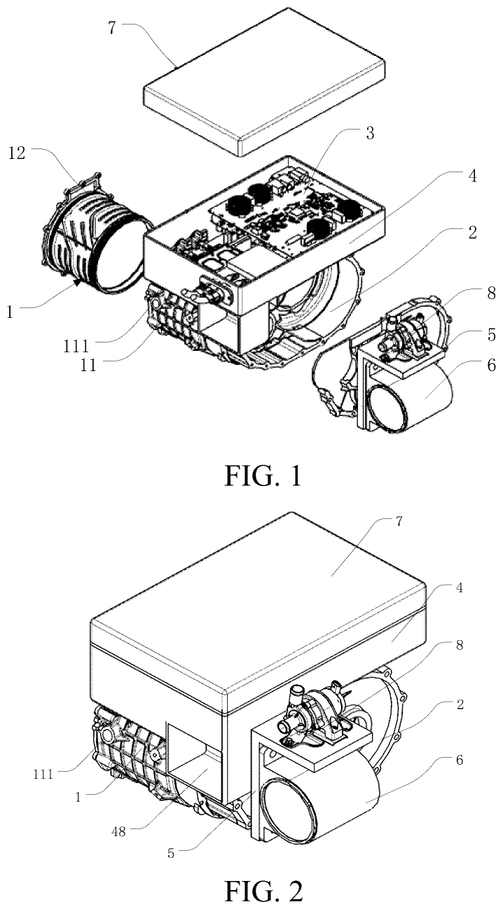

In the present disclosure, in order to better show a structure of the integrated electric drive system and the connection relationship thereof, the term “up” in the present disclosure means an actual direction pointing to the top of the vehicle (that is, above the integrated electric drive system shown in FIG. 2), the term “down” in the present disclosure means an actual direction pointing to the bottom of the vehicle (that is, below the integrated electric drive system shown in FIG. 2), the “left” in the present disclosure means the left of the integrated electric drive system shown in FIG. 2, and the “right” in the present disclosure means the right of the integrated electric drive system shown in FIG. 2.

As shown in FIG. 1 to FIG. 4, an integrated electric drive system provided in an example of the present disclosure includes a motor 1, a speed reducer 2, a controller 3, and a single-piece enclosure 4. A first enclosure space 41 having a first opening and configured for the controller 3 to be mounted is recessed on the single-piece enclosure 4. A second enclosure space 42 configured for the motor 1 to be mounted and a third enclosure space 43 configured for the speed reducer 2 to be mounted are arranged in a direction of the single-piece enclosure 4 facing away from the first opening. The controller 3 is connected with the motor 1. An output shaft 23 of the motor 1 is connected with the speed reducer 2. It may be understood that the first enclosure space 41 is located in the single-piece enclosure 4, and the second enclosure space 42 and the third enclosure space 43 are respectively located on left and right sides below the single-piece enclosure 4. However, the controller 3 includes a motor controller, a vehicle power battery controller, a vehicle power battery charging/discharging device, and the like.

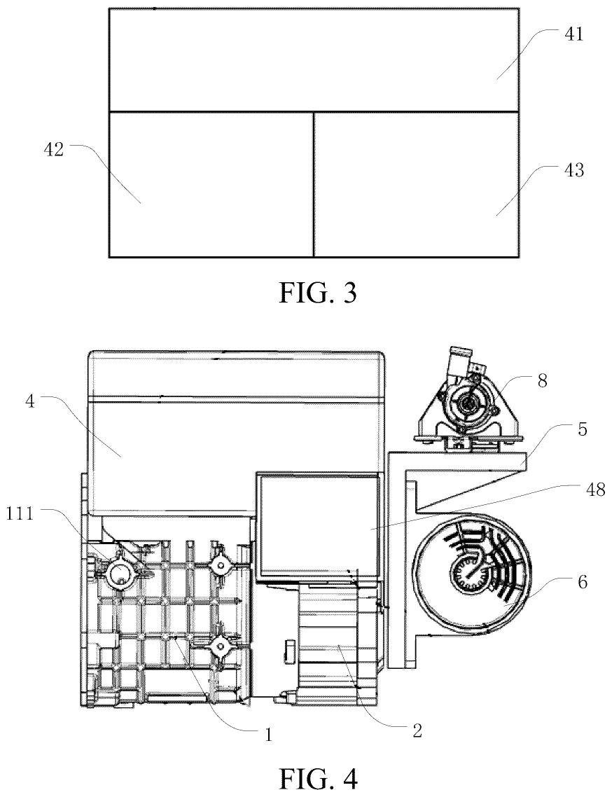

As shown in FIG. 3 and FIG. 4, an absolute value of a difference between a preset mounting width value and a width value of the first enclosure space 41 is less than or equal to a first difference threshold in a direction parallel to the output shaft 23 of the motor 1. The preset mounting width value is a sum of a width value of the second enclosure space 42 and a width value of the third enclosure space 43. In some examples of the present disclosure, the preset mounting width value and the width value of the first enclosure space 41 are substantially the same. That is, the width value of the first enclosure space 41 is substantially equal to a sum of the width value of the second enclosure space 42 and the width value of the third enclosure space 43. In other words, the motor 1 and the speed reducer 2 substantially fill a lower part of the single-piece enclosure 4 in the width direction of the single-piece enclosure 4 (that is, in the direction parallel to the output shaft 23 of the motor 1). It may be understood that the first difference threshold may further be set according to an actual demand, for example, a value range of the first difference threshold is 0-1 cm (for example, 3 mm, 6 mm, 9 mm, and the like).

An absolute value of a difference between a length value of the first enclosure space 41 and a length value of the third enclosure space 43 is less than or equal to a second difference threshold in the direction perpendicular to the output shaft 23 of the motor 1 and parallel to a horizontal plane. In some examples of the present disclosure, the length value of the first enclosure space 41 and the length value of the third enclosure space 43 are substantially the same. That is, the length value of the first enclosure space 41 is substantially equal to a length value of the third enclosure space 43. In other words, the speed reducer 2 substantially fills a lower side of the single-piece enclosure 4 in a length direction of the single-piece enclosure 4. It may be understood that the second difference threshold may further be set according to an actual demand, for example, a value range of the second difference threshold is 0-1 cm (for example, 3 mm, 6 mm, 9 mm, and the like).

In the present disclosure, the integrated electric drive system integrates the controller 3, the motor 1, and the speed reducer 2. The controller 3 is mounted in the first enclosure space 41 within the single-piece enclosure 4, and the motor 1 and the speed reducer 2 are respectively mounted in the second enclosure space 42 and the third enclosure space 43 below the single-piece enclosure 4. In addition, an absolute value of a difference between a sum of the width value of the second enclosure space 42 and the width value of the third enclosure space 43 and the width value of the first enclosure space 41 is less than or equal to the first difference threshold. The absolute value of the difference between the length value of the first enclosure space 41 and the length value of the third enclosure space 43 is less than or equal to the second difference threshold in the direction perpendicular to the output shaft 23 of the motor 1 and parallel to the horizontal plane. Through above arrangement, the mounting spaces of the integrated electric drive system in all directions are more balanced, and no large hanging space is left in all directions, which improves the modality of the single-piece enclosure 4 and noise, vibration, and harshness (NVH) of the vehicle. In addition, the integrated electric drive system has a high integration level, which reduces the mounting space of the integrated electric drive system on the vehicle, thereby providing space for the increase of the motor 1. Moreover, a complex wiring harness connection between the components is omitted in the integrated electric drive system with the high integration level.

In an example, as shown in FIG. 2, an absolute value of a difference between a half of the length value of the first enclosure space 41 and the length value of the second enclosure space 42 is less than or equal to a third difference threshold in a direction perpendicular to the output shaft 23 of the motor 1 and parallel to the horizontal plane. In some examples of the present disclosure, the half of the length value of the first enclosure space 41 and the length value of the second enclosure space 42 are substantially the same. That is, a mounting length of the motor 1 substantially accounts for half of the length of the single-piece enclosure 4 in the length direction of the single-piece enclosure 4, and the length of the second enclosure space 42 substantially accounts for only half of the length of the first enclosure space 41, which is designed according to the shape of the motor 1. It may be understood that the third difference threshold may further be set according to an actual demand, for example, a value range of the third difference threshold is 0-1 cm (for example, 3 mm, 6 mm, 9 mm, and the like). Through the arrangement of the second enclosure space 42, the integrated electric drive system can have a higher integration level, which further improves the NVH of the vehicle.

In an example, as shown in FIG. 1 and FIG. 2, the integrated electric drive system further includes an air conditioning compressor 8 and a support 5 mounted on an end surface of the speed reducer 2 away from the second enclosure space 42. The air conditioning compressor 8 is mounted to the support 5 and connected with the controller 3. In some examples of the present disclosure, the support 5 and the enclosure of the speed reducer 2 are integrally formed. It may be understood that the support 5 and the air conditioning compressor 8 are located on a side surface of the single-piece enclosure 4. The air conditioning compressor 8 is integrated into the integrated electric drive system through the support 5, which further improves the integration level of the integrated electric drive system.

In an example, as shown in FIG. 1 and FIG. 2, the integrated electric drive system further includes a water pump 6 mounted to the support 5 and connected with the controller 3. It may be understood that the water pump 6 may provide a source of water for a vehicle wiper. In addition, the design of the water pump 6 further improves the integration level of the integrated electric drive system.

In an example, as shown in FIG. 1 and FIG. 2, the support 5 includes a vertical plate and a transverse plate connected with an upper end of the vertical plate. The vertical plate is mounted to an end surface of the speed reducer 2 away from the motor 1, and the water pump 6 is mounted above the transverse plate. The air conditioning compressor 8 is mounted to a side of the vertical plate away from the speed reducer 2 and is located below the transverse plate. It may be understood that the water pump 6 is arranged above the support 5, which facilitates a decrease in a length of a connecting pipeline between the water pump 6 and the vehicle wiper, and the air conditioning compressor 8 is mounted below the support 5, which can reserve a large enough space for the connection between the air conditioning compressor 8 and other components of a vehicle air conditioner. In addition, the water pump 6 and the air conditioning compressor 8 are integrated into the integrated electric drive system through the support 5, thereby further improving the integration level of the integrated electric drive system.

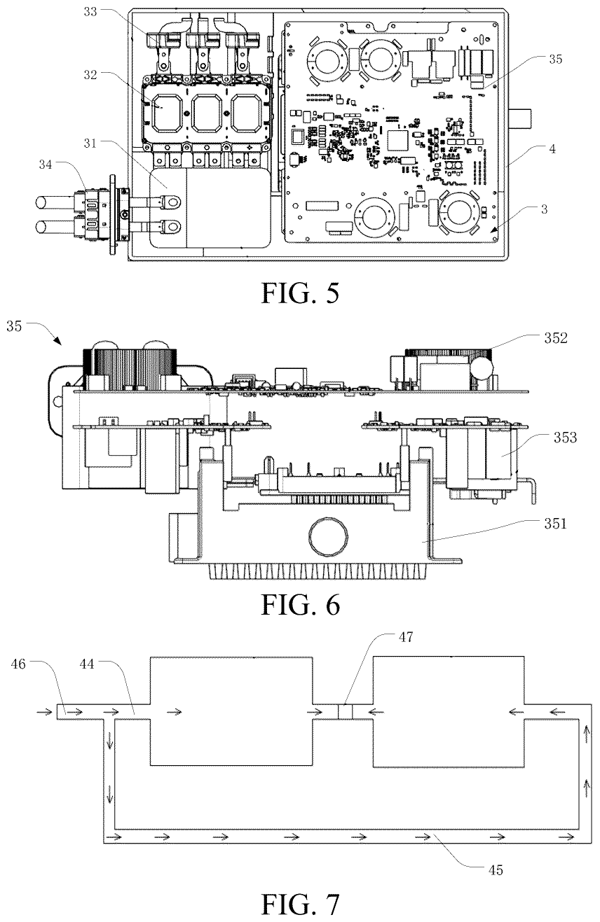

In an example, as shown in FIG. 5, the controller 3 includes a capacitor module 31, an insulated gate bipolar transistor (IGBT) module 32, a three-phase copper bar 33, a DC bus 34, an on-board charger, and a DC converter 35. The on-board charger and the DC converter 35 are both connected with a vehicle power battery. The capacitor module 31, the IGBT module 32, the three-phase copper bar 33, the on-board charger, and the DC converter 35 are all mounted in the first enclosure space 41. The capacitor module 31 is connected with the vehicle power battery through the DC bus 34 mounted to the single-piece enclosure 4. The three-phase copper bar 33 is connected with a three-phase terminal of the motor 1. It may be understood that the on-board charger and the DC converter 35 is a device integrating the on-board charger and the DC converter. The on-board charger has the ability to fully charge the vehicle power battery safely and automatically. The on-board charger can dynamically adjust a charging current and a charging voltage and execute a corresponding action to complete the charging process of the vehicle power battery. However, the DC converter may convert a high voltage of the vehicle power battery to a low voltage required by a storage battery on the vehicle. The design of the on-board charger and the DC converter 35 further improves the integration level of the controller 3.

The vehicle power battery drives the motor 1 to rotate through the DC bus 34, the capacitor module 31, the IGBT module 32, and the three-phase copper bar 33 connected in sequence. It may be understood that the vehicle power battery drives the motor 1 to rotate through the above route, and the motor 1 drives vehicle wheels to rotate through the speed reducer 2, thereby realizing the technical effect of the vehicle power battery driving the vehicle wheels to rotate.

In an example, as shown in FIG. 6, the on-board charger and the DC converter 35 include a heat dissipation module 351, an electric control element driving module 352, and a heating element driving module 353. The heating element driving module 353 is mounted to the heat dissipation module 351, and the electric control element driving module 352 is mounted to an end of the heating element driving module 353 away from the heat dissipation module 351. It may be understood that the heat dissipation module 351 is integrated with a heat dissipation member such as a straight cold plate, and the electric control element driving module 352 is mainly integrated with an electric control element of the on-board charger and the DC converter 35 (for example, the electric control element driving module 352 is integrated with electric control elements generating little heat such as a vehicle controller, a controller of the air conditioning compressor 8, a controller of the water pump 6, and a controller of the vehicle power battery). The heating element driving module 353 is mainly integrated with heating elements of the on-board charger and the DC converter 35 (for example, the heating element driving module 353 is integrated with heating elements generating much heat such as the vehicle controller, the controller of the air conditioning compressor 8, the controller of the water pump 6, and the controller of the vehicle power battery). That is to say, the on-board charger and the DC converter 35 include 3 layers. A middle layer is the heating element driving module 353, a lower layer is the electric control element driving module 352, and an upper layer is the heat dissipation module 351. Since the heat dissipation module 351 contacts the cooling water channel inside the single-piece enclosure 4, the layer distributed design of the on-board charger and the DC converter 35 improves the heat dissipation efficiency of the on-board charger and the DC converter 35.

In an example, as shown in FIG. 5, the first enclosure space 41 includes a first internal space and a second internal space both arranged in a rectangular shape and adjacent to each other. It may be understood that the first internal space and the second internal space are respectively located on left and right sides of the single-piece enclosure 4.

The capacitor module 31, the IGBT module 32, and the three-phase copper bar 33 are mounted in the first internal space. The on-board charger and the DC converter 35 are mounted in the second internal space, and the DC bus 34 is located on a side of the first internal space facing away from the second internal space. In some examples of the present disclosure, the capacitor module 31, the IGBT module 32, and the three-phase copper bar 33 are arranged in the first internal space in sequence. It may be understood that the capacitor module 31, the IGBT module 32, the three-phase copper bar 33, and the on-board charger and the DC converter 35 are orderly mounted in the first enclosure space 41, so that the complex wiring harness connection between the components of the controller 3 is omitted, which enhances the compactness and reliability of the integrated electric drive system and improves the modality of the controller 3.

In an example, as shown in FIG. 7, the single-piece enclosure 4 includes a first cooling water channel 44, a second cooling water channel 45, a water channel inlet, and a water channel outlet 47. The first cooling water channel 44 is arranged at a position in the single-piece enclosure 4 opposite to the IGBT module 32, and the second cooling water channel 45 is arranged at a position in the single-piece enclosure 4 opposite to the on-board charger and the DC converter 35. It may be understood that the first cooling water channel 44 is mainly configured to absorb heat dissipated by the IGBT module 32, and the second cooling water channel 45 is mainly configured to absorb heat dissipated by the on-board charger and the DC converter 35. Specifically, multiple protrusions are arranged on a lower part of the heat dissipation module 351 of the on-board charger and the DC converter 35, and the protrusions are arranged opposite to the second cooling water channel 45. The protrusions can increase a contact area between the heat dissipation module 351 and the second cooling water channel 45, thereby improving the heat dissipation efficiency of the heat dissipation module 351.

One end of the water channel inlet is connected with a preset water inlet device, the other end of the water channel inlet is connected with the first cooling water channel 44 and the second cooling water channel 45, and the water channel outlet 47 is connected with ends of the first cooling water channel 44 and the second cooling water channel 45 away from the water channel inlet. It may be understood that the first cooling water channel 44 and the second cooling water channel 45 are connected in parallel between the water channel inlet 46 and the water channel outlet 47. In the present disclosure, the design of the first cooling water channel 44 and the second cooling water channel 45 enhances the heat dissipation efficiency of the controller 3, and then increases the service life of the integrated electric drive system.

In an example, as shown in FIG. 1 and FIG. 2, the motor 1 includes an outer enclosure 11 connected with the speed reducer 2 and an inner enclosure 12 inserted in the outer enclosure 11. A cooling space is formed between an inner wall of the outer enclosure 11 and an outer wall of the inner enclosure 12. A water inlet and a water outlet 111 both in communication with the cooling space are arranged on the outer enclosure 11. An end of the water channel outlet 47 away from the first cooling water channel 44 is in communication with the water inlet. It may be understood that the design of the cooling space can improve the heat dissipation efficiency of the motor 1, thereby extending the service life of the motor 1.

Specifically, the cooling liquids in two paths flow in from the water channel inlet. The cooling liquid in one path absorbs heat of the IGBT module 32 through the first cooling water channel 44, and the cooling liquid in the other path absorbs heat dissipated by the on-board charger and the DC converter 35 through the second cooling water channel 45. The cooling liquids in two paths are collected through the water channel outlet 47 and flow through the water inlet into the cooling space. The cooling liquid absorbs the heat dissipated by the motor 1 in the cooling space and flows out from the water outlet 111. In the present disclosure, the cooling liquid can cool the IGBT module 32, the on-board charger and the DC converter 35, and the motor 1, which increases the utilization rate of the cooling liquid.

In an example, as shown in FIG. 1 and FIG. 2, multiple ribbed flow guide plates are arranged on the outer wall of the inner enclosure 12 in a circumferential direction of the output shaft 23 of the motor 1. It may be understood that the ribbed flow guide plates can cause the cooling liquid in the cooling space to flow in a circumferential direction of the inner enclosure 12, thereby enhancing the cooling efficiency of the motor 1.

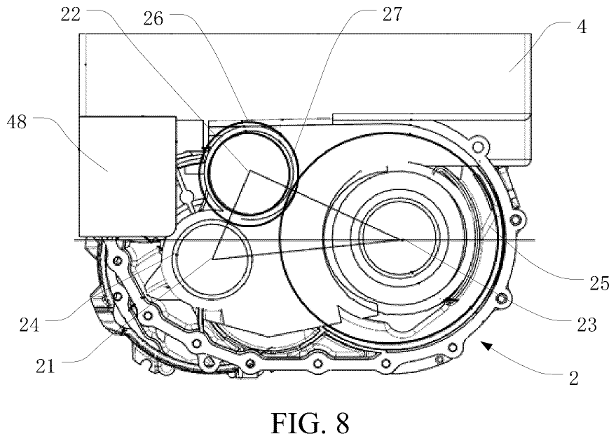

In an example, as shown in FIG. 8, the speed reducer 2 includes a main shaft 21, an intermediate shaft 22, an output shaft 23, a driving gear 24, an output gear 25, an intermediate driving gear 26, and an intermediate driven gear 27. The main shaft 21 is connected with the output shaft of the motor 1. The driving gear 24 is mounted to the main shaft 21, the intermediate driving gear 26 and the intermediate driven gear 27 are both mounted to the intermediate shaft 22, and the output gear 25 is mounted to the output shaft 23. The intermediate driving gear 26 is meshed with the driving gear 24. The intermediate driven gear 27 is meshed with the output gear 25. It may be understood that the output shaft 23 of the motor 1 passes through the main shaft 21, the driving gear 24, the intermediate driving gear 26, the intermediate shaft 22, the intermediate driven gear 27, the output gear 25, and the output shaft 23 in sequence, and then drives the vehicle wheel to rotate.

An axis of the intermediate shaft 22 is higher than axes of the main shaft 21 and the output shaft 23. An included angle between a line connecting a center point of the main shaft 21 to a center point of the output shaft 23 and the horizontal plane is less than or equal to a preset angle on a plane perpendicular to the axis of the main shaft 21. The preset angle may be set according to the design requirement. For example, a value range of the preset angle is −10 degrees to 10 degrees. In some examples of the present disclosure, an included angle between a line connecting a center point of the main shaft 21 to a center point of the output shaft 23 and the horizontal plane is substantially equal to 0 degrees. It may be understood that the intermediate shaft 22 is located above the main shaft 21 and the output shaft 23, and the intermediate driving gear 26 and the intermediate driven gear 27 are both located above the driving gear 24 and the output gear 25. The design of the speed reducer 2 can reduce the center of gravity of the integrated electric drive system and the center of gravity of the vehicle, thereby improving the driving stability of the vehicle and increasing the driving pleasure of the vehicle.

In an example, as shown in FIG. 1 and FIG. 2, a battery mounting space 48 configured for a battery to be mounted is arranged on an end surface of the single-piece enclosure 4 facing away from the first opening. It may be understood that the integrated electric drive system further includes a battery mounted in the battery mounting space 48. In an example, as shown in FIG. 2, the battery mounting space 48 has a second opening, and a direction of the second opening is perpendicular to a direction of the second opening. It may be understood that the battery mounting space 48 is integrated below the single-piece enclosure 4, so that the battery can be mounted in the battery mounting space 48. It should be noted that the battery is a small battery of 12 V. The small battery is usually used for a low power subsystem of the vehicle, such as a vehicle door opening/closing subsystem, a vehicle start subsystem, and a vehicle light subsystem. The design of the battery further improves the integration level of the integrated electric drive system.

In an example, as shown in FIG. 1 and FIG. 2, the integrated electric drive system further includes an enclosure cover 7 matching the first opening. It may be understood that the enclosure cover 7 is connected with the single-piece enclosure 4, so as to protect the controller 3 inside the single-piece enclosure 4.

The foregoing descriptions are merely preferred examples of the present disclosure, but are not intended to limit the present disclosure. Any modification, equivalent replacement, or improvement made within the spirit and principle of the present disclosure shall fall within the protection scope of the present disclosure.

What is claimed is:

1. An integrated electric drive system, comprising a motor, a speed reducer, a controller, and a single-piece enclosure, wherein:
a first enclosure space having a first opening and configured for the controller to be mounted is recessed on the single-piece enclosure; a second enclosure space configured for the motor to be mounted and a third enclosure space configured for the speed reducer to be mounted are disposed in a direction of the single-piece enclosure facing away from the first opening; the controller is connected with the motor; and an output shaft of the motor is connected with the speed reducer;
a mounting width value and a width value of the first enclosure space are about the same in a direction parallel to the output shaft of the motor; and
the mounting width value is a sum of a width value of the second enclosure space and a width value of the third enclosure space.

2. The integrated electric drive system according to claim 1, wherein a length value of the first enclosure space and a length value of the third enclosure space are about the same in a direction perpendicular to the output shaft of the motor and parallel to a horizontal plane.

3. The integrated electric drive system according to claim 1, wherein:
the speed reducer comprises a main shaft, an intermediate shaft, an output shaft, a driving gear, an output gear, an intermediate driving gear, and an intermediate driven gear; the main shaft is connected with the output shaft of the motor; the driving gear is mounted to the main shaft; the intermediate driving gear and the intermediate driven gear are mounted to the intermediate shaft; the output gear is mounted to the output shaft of the speed reducer; the intermediate driving gear is meshed with the driving gear; and the intermediate driven gear is meshed with the output gear; and
an axis of the intermediate shaft is higher than axes of the main shaft and the output shaft of the speed reducer; and an angle between a line connecting a center point of the main shaft to a center point of the output shaft of the speed reducer and a horizontal plane is less than or equal to a preset angle on a plane perpendicular to the axis of the main shaft.

4. The integrated electric drive system according to claim 3, wherein a range of the preset angle is about −10 degrees to 10 degrees.

5. The integrated electric drive system according to claim 1, wherein an absolute value of a difference between the mounting width value and the width value of the first enclosure space is less than or equal to a first difference threshold, and a value of the first difference threshold is about 1 cm.

6. The integrated electric drive system according to claim 2, wherein an absolute value of a difference between the length value of the first enclosure space and the length value of the third enclosure space is less than or equal to a second difference threshold, and a value of the second difference threshold is about 1 cm.

7. The integrated electric drive system according to claim 1, wherein an absolute value of a difference between the mounting width value and the width value of the first enclosure space is greater than 0.

8. The integrated electric drive system according to claim 1, wherein a length value of the second enclosure space and a half of the length value of the first enclosure space in the direction perpendicular to the output shaft of the motor and parallel to a horizontal plane are about the same.

9. The integrated electric drive system according to any of claim 8, wherein an absolute value of a difference between the length value of the second enclosure space and the half of the length value of the first enclosure space is less than or equal to a third difference threshold, and the third difference threshold is about 1 cm.

10. The integrated electric drive system according to claim 1, wherein:
the controller comprises a capacitor module, an insulated gate bipolar transistor (IGBT) module, a three-phase copper bar and a DC bus; the capacitor module, the IGBT module and the three-phase copper bar are mounted in the first enclosure space; the capacitor module is connected with a vehicle power battery through the DC bus mounted to the single-piece enclosure; and the three-phase copper bar is connected with a three-phase terminal of the motor; and
the vehicle power battery drives the motor to rotate through the DC bus, the capacitor module, the IGBT module, and the three-phase copper bar connected in sequence.

11. The integrated electric drive system according to claim 1, wherein:
the single-piece enclosure comprises a first cooling water channel, a water channel inlet, and a water channel outlet;
one end of the water channel inlet is connected with a preset water inlet device;
the other end of the water channel inlet is connected with the first cooling water channel; and
the water channel outlet is connected with an end of the first cooling water channel away from the water channel inlet.

12. The integrated electric drive system according to claim 1, further comprising an enclosure cover adaptively connected with the first opening.

13. An electric vehicle, comprising an integrated electric drive system, and the integrated electric drive system comprising a motor, a speed reducer, a controller, and a single-piece enclosure, wherein:
a first enclosure space having a first opening and configured for the controller to be mounted is recessed on the single-piece enclosure; a second enclosure space configured for the motor to be mounted and a third enclosure space configured for the speed reducer to be mounted are disposed in a direction of the single-piece enclosure facing away from the first opening; the controller is connected with the motor; and an output shaft of the motor is connected with the speed reducer;
a mounting width value and a width value of the first enclosure space are about the same in a direction parallel to the output shaft of the motor; and
the mounting width value is a sum of a width value of the second enclosure space and a width value of the third enclosure space.

14. The electric vehicle according to claim 13, wherein a length value of the first enclosure space and a length value of the third enclosure space are about the same in a direction perpendicular to the output shaft of the motor and parallel to a horizontal plane.

15. The electric vehicle according to claim 13, wherein:
the speed reducer comprises a main shaft, an intermediate shaft, an output shaft, a driving gear, an output gear, an intermediate driving gear, and an intermediate driven gear; the main shaft is connected with the output shaft of the motor; the driving gear is mounted to the main shaft; the intermediate driving gear and the intermediate driven gear are mounted to the intermediate shaft; the output gear is mounted to the output shaft of the speed reducer; the intermediate driving gear is meshed with the driving gear; and the intermediate driven gear is meshed with the output gear; and
an axis of the intermediate shaft is higher than axes of the main shaft and the output shaft of the speed reducer; and an angle between a line connecting a center point of the main shaft to a center point of the output shaft of the speed reducer and a horizontal plane is less than or equal to a preset angle on a plane perpendicular to the axis of the main shaft.

16. The electric vehicle according to claim 15, wherein a range of the preset angle is about −10 degrees to 10 degrees.

17. The electric vehicle according to claim 13, wherein an absolute value of a difference between the mounting width value and the width value of the first enclosure space is less than or equal to a first difference threshold, and a value of the first difference threshold is about 1 cm.

18. The electric vehicle according to claim 14, wherein an absolute value of a difference between the length value of the first enclosure space and the length value of the third enclosure space is less than or equal to a second difference threshold, and a value of the second difference threshold is about 1 cm.

19. The electric vehicle according to claim 13, wherein an absolute value of a difference between the mounting width value and the width value of the first enclosure space is greater than 0.

20. The electric vehicle according to claim 13, wherein a length value of the second enclosure space and a half of the length value of the first enclosure space in the direction perpendicular to the output shaft of the motor and parallel to a horizontal plane are about the same.
